(19) United States
(12) Patent Application Publication
(10) Pub. No.: US 2015/0142348 A1
(43) Pub. Date: May 21, 2015

(54) POWER CALCULATING METHOD ADAPTED TO WIRELESS POWER SYSTEM

(71) Applicant: RICHTEK TECHNOLOGY CORP, Hsinchu County (TW)

(72) Inventors: Wei-Jen Huang, Hsinchu (TW); Shui-Mu Lin, Hsinchu (TW)

(73) Assignee: RICHTEK TECHNOLOGY CORP, Hsinchu County (TW)

(21) Appl. No.: 14/195,557

(22) Filed: Mar. 3, 2014

(30) Foreign Application Priority Data
Nov. 18, 2013 (TW) 102141882

(51) Int. Cl. G01R 21/133; G01V 3/00

(52) U.S. Cl. CPC G01R 21/133; G01V 3/00
USPC 702/61

(57) ABSTRACT

A power calculating method, adapted to a wireless power system, includes the following steps: first, multi-sampling input or output current of a regulator in the power receiving end, and performing root-men-square calculation accordingly to derive a current RMS value; second, multi-sampling input or output voltage of the regulator, and performing a root-men-square calculation accordingly to derive a voltage RMS value; third, multiplying the voltage RMS value to the current RMS value and a cosine of an angle to derive a regulating power value; fourth, dividing the regulating power value by a power efficiency value to derive a receiving power value; finally, transmitting the receiving power value to a power transmitting end of the wireless power system for performing foreign object detection.

### CROSS-REFERENCES TO RELATED APPLICATIONS

This non-provisional application claims priority under 35 U.S.C. §119(a) on Patent Application No. 102141882 filed in Taiwan, R.O.C. on 18^{th} Nov. 2013, the entire contents of which are hereby incorporated herein by reference.

### BACKGROUND

1. Technical Field

This present invention relates to a power calculating method and, more specifically, to a power calculating method adapted to a wireless power system for performing foreign object detection.

2. Description of Related Art

Wireless power, also known as wireless energy transmission, is a technique which takes advantage of near-field coupling, for example inductive coupling, to transmit energy from a power supplying equipment to an electric device. For example in the application of wireless charging, an electronic device receives energy via wireless power for charging a battery and providing required power for operation. Since the energy transmission between the electronic device and the power supplying equipment is realized by inductive coupling without conducting wires, no conducting point is exposed on both the electronic device and the power supplying equipment. Therefore, the danger of electric shot by contacting can be avoided, and the un-exposed metal parts can be free from oxidation by water vapor or oxygen. Besides, the mechanical degradation and the possible danger caused by spark, both of which are caused by connecting and separating the electronic device and the power supplying equipment, can also be avoided.

The technical development on wireless power brings great contribution on the medical applications and consumer electronics. The wireless power technique makes medical implant device safer. Without conducting wires penetrating skin and other body tissues, patient can charging the medical implant device without harming body tissues and free from the risk of infection. The wireless power technique also brings great convenience on consumer electronics since devices can be charged merely by being placed in the vicinity of the wireless charger, and the wires are obsoleted. Besides, technically a wireless charger can charge many electronic devices at the same time which saves wires, adaptors and power outlets.

FIG. 1 is a schema of a wireless power system 100 of prior art. The wireless power system 100 includes a wireless power transmitting end and a wireless power receiving end. The wireless power transmitting end includes a power supply 110, a supply coupling capacitor 120 and primary windings 130. The wireless power receiving end includes secondary windings 150, oscillating capacitors 160 and 165. The wireless power transmitting end transmits a wireless power 140 of alternating current (AC), and the wireless power receiving end receives the wireless power 140 by near-field coupling, for example (but not limited to) inductive coupling between first windings 130 and second windings 150, to generate an AC power into a rectifier 170. Besides, the oscillating circuit including secondary windings 150, the oscillating capacitors 160 and 165 results in the effect of band-pass filtering and renders the wireless power receiver end become selective to the AC frequency of the wireless power 140. The rectifier 170 is adopted to rectify the received AC power into a direct-current (DC) voltage. The wireless power system 100 can further includes a regulator 180 which receives the DC voltage from rectifier 170 and generates a stable output voltage to supply a load 190. In the application of wireless charging, the regulator 180 generates a regulated output voltage or output current to charge a battery.

However, in the case that a foreign object exists on the path of the wireless power 140 between the wireless power transmitting end and the wireless power receiving end, the foreign object is prone to drain the energy of the wireless power 140 causing the power loss of the wireless power system 100. Moreover, the foreign object will influence the magnetic field of the wireless power 140 and incur abnormal distribution of temperature which causes possible danger due to high temperature. Hence, in a wireless power system, the foreign object detection (FOD) is performed to detect a foreign object on the path of the wireless power and further preclude the abnormal condition. FOD is realized by comparing the difference of power quantity between the transmitted power by the wireless power transmitting end and the received power of the wireless power receiving end. When the difference is large, the case is determined that there's possibly a foreign object on the path of the wireless power. Subsequently, the abnormal condition should be precluded in order to utilize the wireless power system normally and safely.

FIG. 2 is a schema showing a power calculating method in a wireless power system, such as the wireless power system 100 of FIG. 1, of prior art. The regulator 180 of the wireless power system 100 is a linear regulator, of which the input current and the output current are almost the same under normal operation. In the wireless power system 100, the instantaneous input voltage and the instantaneous output current are detected, which are the detecting voltage and the detecting current of FIG. 2 respectively, and multiplied to each other to derive a receiving power value, which is then transmitted to the power transmitting end for performing foreign object detection. There are at least the following disadvantages in such prior art resulting in inaccuracy of the application. First, the receiving power value in FIG. 2 is an instantaneous power, which has possibly abrupt changes from time to time. As a result, a higher sampling rate is required for detection and a larger bandwidth is required to send the data back to the wireless power transmitting end. Second, the power loss of the front end of the wireless power receiving end and the power loss of the rectifier 170 are not considered in the calculated receiving power value. Therefore, a considerable error may exist between the calculated receiving power value and the real power received by the wireless power receiving end.

### SUMMARY

In view of above problems, the objective of the present invention is to provide a power calculating method adapted to a wireless power system for performing foreign object detection.

In one embodiment, a power calculating method adapted to a power receiving end of a wireless power system for performing foreign object detection is disclosed. The power calculating method includes the following steps:

Multi-sampling an input current or an output current of a regulator in the power receiving end to derive a current array, and perform a root-men-square calculation on the current array to derive a current RMS value. Multi-sample an input voltage or an output voltage of the regulator to derive a voltage array, and perform a root-men-square calculation on the voltage array to derive a voltage RMS value. Multiply the voltage RMS value to the current RMS value and a cosine of an angle to derive a regulating power value, wherein the angle is correlated to a signal phase difference between the multi-sampled input voltage or output voltage of the regulator and the multi-sampled input current or output current of the regulator. Dividing the regulating power value by a power efficiency value to derive a receiving power value, wherein the power efficiency value is a function of the current RMS value. Transmit the receiving power value to a power transmitting end of the wireless power system for performing foreign object detection.

In another embodiment, a power calculating method adapted to a power receiving end of a wireless power system for performing foreign object detection is disclosed. The power calculating method includes the following steps:

Sample an input current or an output current of a regulator in the power receiving end to derive a current sampling value, meanwhile sample an input voltage or an output voltage of the regulator to derive a voltage sampling value. Multiply the current sampling value to the voltage sampling value to derive a product, and then divide the product by a power efficiency value to derive an instant receiving power value, wherein the power efficiency value is a function of the current sampling value. Repeat the step of deriving the current sampling value and the voltage sampling value for a plurality of times to derive the plurality of instant receiving power values, and calculate the average value of the plurality of instant receiving power values to derive a receiving power value. Transmitting the receiving power value to a power transmitting end of the wireless power system for performing foreign object detection.

The present invention is advantageous because the more accurate power calculating result can be derived for performing better FOD and power efficiency optimization.

### BRIEF DESCRIPTION OF THE DRAWINGS

These and other objectives of the present invention will no doubt become obvious to those of ordinary skill in the art after reading the following detailed description of the preferred embodiments that is illustrated in the various figures and drawings, in which:

FIG. 1 is a schema of a wireless power system 100 of prior art.

FIG. 2 is a schema showing a power calculating method in a wireless power system of prior art.

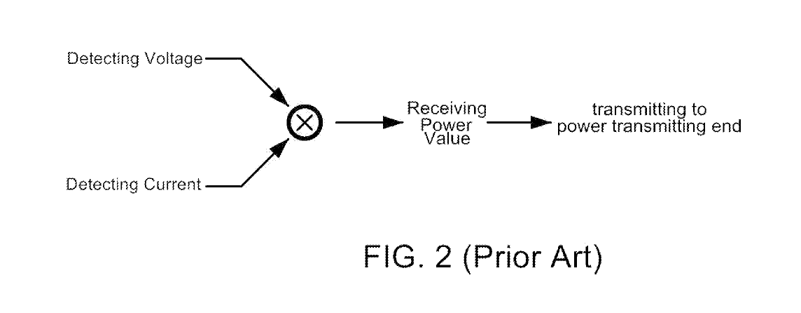

FIG. 3 is a schema showing a power calculating method of the first embodiment of the present invention.

FIG. 4 is a schema showing a power calculating method of the second embodiment of the present invention.

FIG. 5 is the concluded flow chart of the first embodiment of the present invention disclosed in FIG. 3.

FIG. 6 is a schema showing a power calculating method of the third embodiment of the present invention.

FIG. 7 is a schema showing a power calculating method of the fourth embodiment of the present invention.

FIG. 8 is the concluded flow chart of the third embodiment of the present invention disclosed in FIG. 6.

### DETAILED DESCRIPTION OF THE EMBODIMENTS

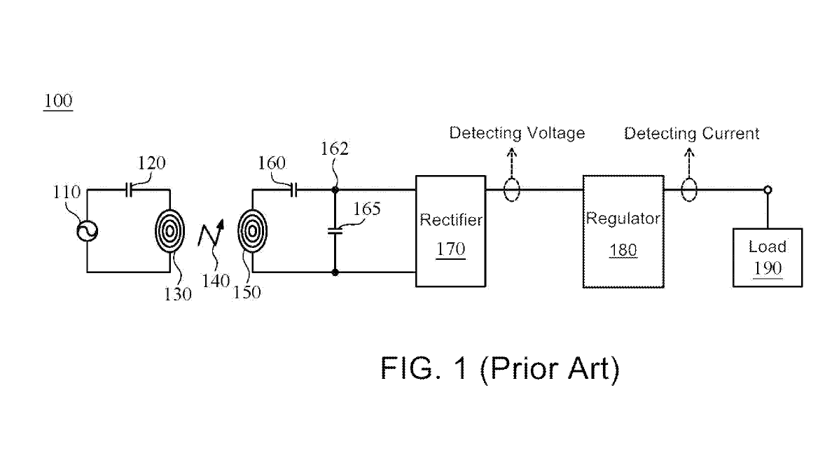

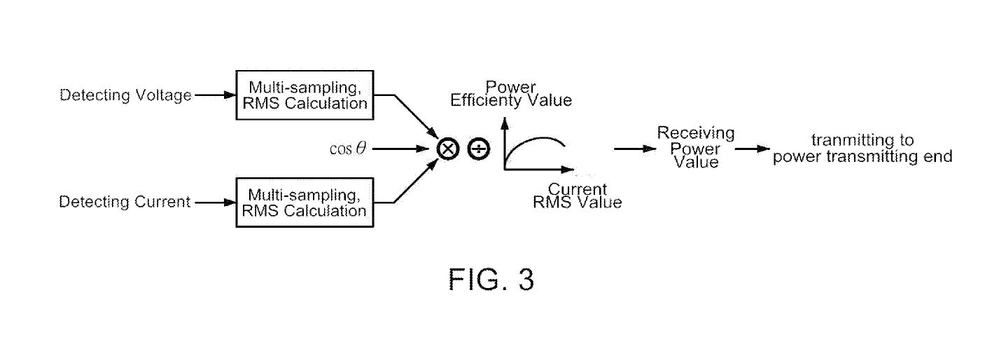

FIG. 3 is a schema showing a power calculating method of the first embodiment of the present invention. The power calculating method is adapted to a wireless power system, for example to the wireless power receiving end in FIG. 1. The power calculating method disclosed in the present invention can be adopted to perform FOD or power efficiency optimization in the wireless power system 100. The first step of the power calculating method is to multi-sample the input or output current of the regulator and the input or output voltage of the regulator. It is worth noting that the decision of whether the input current (voltage) or the output current (voltage) is sampled depends on various considerations of the application, such as the rated electrical characteristics of the sampling circuit, the more stable signal among the input current (voltage) and the output current (voltage), or the minimization of the physical size of the circuit. In the first embodiment, the input voltage and the output current, which are regarded as the detecting voltage and the detecting current in FIG. 3 respectively, are multi-sampled as is shown in FIG. 1. The topology is adopted for interpreting the invention but not to limit the scope of the invention. Besides, the prior arts of the voltage and current sampling techniques are well known. People skilled in the art can choose proper topologies according to various applications after they understand the technique and the related descriptions of this invention. Hence, the sampling techniques will not be interpreted further hereinafter.

After multi-sampling the detecting voltage and the detecting current to derive a voltage array and a current array respectively, the root-mean-square calculation are performed on the voltage array and the current array respectively to derive a voltage RMS value and a current RMS value. It is worth noting that the voltage sampling time instant and the current sampling time instant can be asynchronous, and the power calculating method of the disclosed invention can still work well.

Then, multiplying the voltage RMS value to the current RMS value and a cosine of an angle to derive a regulating power value. The angle is correlated to a signal phase difference between the detecting voltage and the detecting current. This is because when the detecting voltage and the detecting current are periodic in one multi-sampling event, the power calculation is correlated to the phase difference between the detecting voltage and the detecting current. In such a case that the detecting voltage and the detecting current are DC type, the angle is 0 degree; that is, the cosine of the angle is 1.

Further, dividing the regulating power value by a power efficiency value to derive a receiving power value. The power efficiency value is defined as the power converting efficiency between some stage of the wireless power system 100 and the regulator 180. This definition can be adjusted according to the application. For example, the power efficiency value can be defined as the power converting efficiency between the secondary windings 150 and the regulator 180, thus the calculated receiving power value represents the received wireless power of the secondary windings 150. In another case that the rectifier 170 and the regulator 180 are integrated in an integrated circuit (IC), which is implemented by semiconductor process, the power efficiency value can be defined as the power converting efficiency between the rectifier 170 and the regulator 180 to adapt to different choices of the part of secondary windings 150 in various applications of the IC. In this case, the receiving power value represents the received wireless power of the rectifier 170. Furthermore, when the normal power converting efficiency of the path of wireless power 140 is known by the wireless power receiving end, the power efficiency value can be defined as the power converting efficiency between the first windings 130 and the regulator 180, by which the wireless power transmitted by the first windings 130 can be calculated. Besides, if the input voltage and the input current of the regulator 180 are not chosen to be the detecting voltage and the detecting current at the same time, the power efficiency value should include the power converting efficiency of the regulator 180.

In more detail, the power efficiency value is usually not a fixed number but a function of a current, such as a function of the current RMS value in the first embodiment of FIG. 3. Hence, after the detecting current is multi-sampled and the root-mean-squared calculation is performed to derive the current RMS value, the corresponding power efficiency value can be deduced according to the current RMS value and the receiving power value can be further derived. Assume the elements of the voltage array are V₁, V₂, . . . , V_{N}, and the elements of the current array are I₁, I₂, . . . , I_{N}, the power efficiency value corresponding to the current RMS value is E, the aforementioned angle is, then the receiving power value P can be derived as follows:

$$P = \frac{\frac{\sqrt{{V}_{1}^{2} + {V}_{2}^{2} + … + {V}_{N}^{2}}}{N} \times \frac{\sqrt{{I}_{1}^{2} + {I}_{2}^{2} + … + {I}_{N}^{2}}}{N} \times cos θ}{E} . \qquad ( 1 )$$

Finally, the receiving power value is transmitted to the power transmitting end of the wireless power system 100 for performing such as FOD or power efficiency optimization. The transmitting method of the receiving power value is mainly by wireless transmission which is well known by people in the skill, and will not be interpreted further hereinafter.

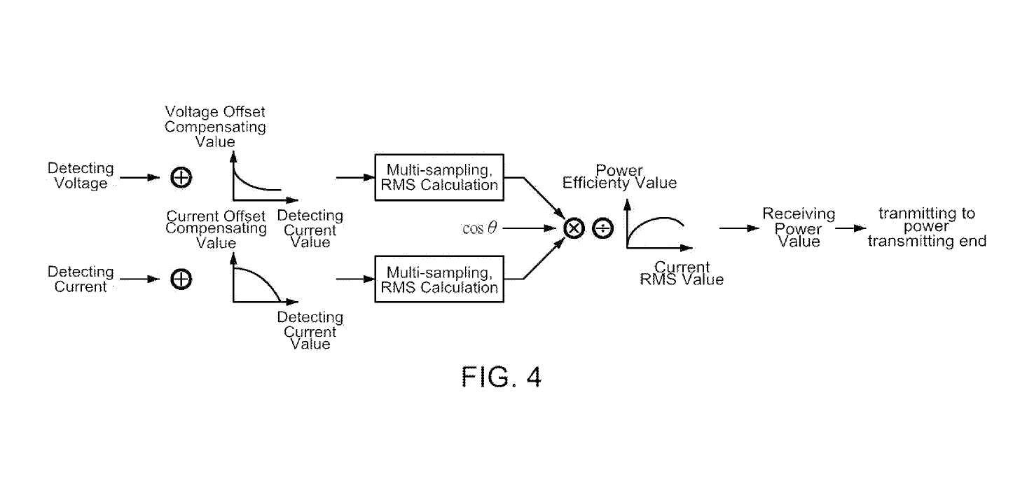

FIG. 4 is a schema showing a power calculating method of the second embodiment of the present invention. The difference between the second embodiment disclosed in FIG. 4 and the first embodiment disclosed in FIG. 3 is that the voltage offset compensation and the current offset compensation is added in the second embodiment. As for the rest parts of the second embodiment of FIG. 4, they can be directly referred to the corresponding parts of the first embodiment.

As is shown in FIG. 4, since there are possible offset in the voltage and current sampling circuits, after multi-sampling the detecting voltage and the detecting current, a voltage offset compensating value and a current offset compensating value are added to each sampled value of the detecting voltage and the detecting current respectively to compensate for the offset. In the real implementation, it is found that the voltage offset compensating value and the current offset compensating value can both be functions of the detecting current value for the optimized compensation effect. Nonetheless, the voltage offset compensating value and the current offset compensating value can also be fixed values, or functions of other parameters. People of the skill can optimize the decision of the voltage offset compensating value and the current offset compensating value according to the various applications.

In more detail, assume the voltage offset compensating values corresponding to the multi-sampled values of the detecting voltage V₁, V₂, . . . , V_{N} respectively are Vₒₛ₁, Vₒₛ₂, . . . , V_{osN}, and the current offset compensating values corresponding to the multi-sampled values of the detecting current I₁, I₂, . . . , I_{N} respectively are Iₒₛ₁, Iₒₛ₂, . . . , I_{osN}, the power efficiency value corresponding to the current RMS value is E, the aforementioned angle is, then the receiving power value P can be derived as follows:

$$P = \frac{\begin{matrix}\frac{\sqrt{{( {V}_{1} + {V}_{os 1} )}^{2} + {( {V}_{2} + {V}_{os 2} )}^{2} + … + {( {V}_{N} + {V}_{osN} )}^{2}}}{N} \times \\ \frac{\sqrt{{( {I}_{1} + {I}_{os 1} )}^{2} + {( {I}_{2} + {I}_{os 2} )}^{2} + … + {( {I}_{N} + {I}_{osN} )}^{2}}}{N} \times cos θ\end{matrix}}{E} . \qquad ( 2 )$$

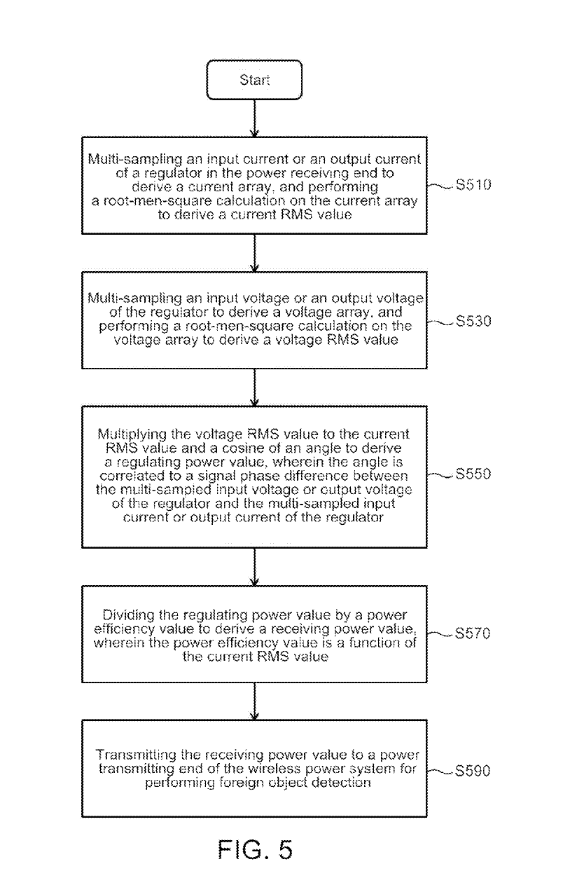

FIG. 5 is the concluded flow chart of the first embodiment of the present invention disclosed in FIG. 3. The flow chart includes the following steps:

As shown in step S510, multi-sample an input current or an output current of a regulator in the power receiving end to derive a current array, and perform a root-men-square calculation on the current array to derive a current RMS value.

As shown in step S530, multi-sample an input voltage or an output voltage of the regulator to derive a voltage array, and perform a root-men-square calculation on the voltage array to derive a voltage RMS value.

As shown in step S550, multiply the voltage RMS value to the current RMS value and a cosine of an angle to derive a regulating power value, wherein the angle is correlated to a signal phase difference between the multi-sampled input voltage or output voltage of the regulator and the multi-sampled input current or output current of the regulator.

As shown in step S570, divide the regulating power value by a power efficiency value to derive a receiving power value, wherein the power efficiency value is a function of the current RMS value.

As shown in step S590, transmit the receiving power value to a power transmitting end of the wireless power system for performing FOD.

Besides, step S510 can further include adding a current offset compensating value to the multi-sampled values of the input or output current to derive the current array, wherein the current offset compensating value can be a function of the multi-sampled input or output current of the regulator.

Further, step S530 can further include adding a voltage offset compensating value to the multi-sampled values of the input or output voltage to derive the voltage array, wherein the voltage offset compensating value can be a function of the multi-sampled input or output current of the regulator.

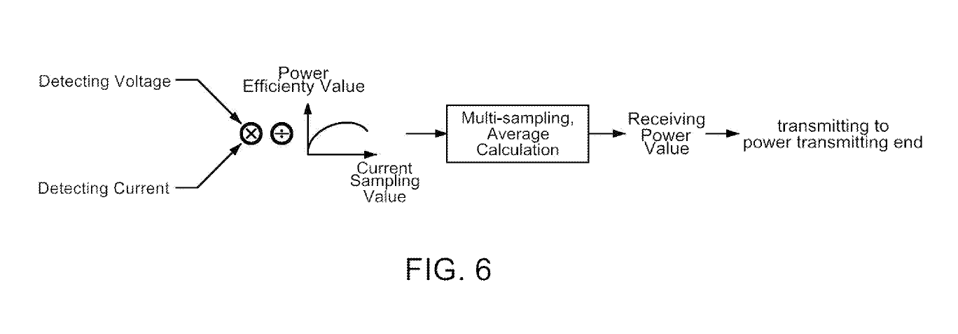

FIG. 6 is a schema showing a power calculating method of the third embodiment of the present invention. The power calculating method is adapted to a wireless power system, for example to the wireless power receiving end in FIG. 1. The power calculating method disclosed in the present invention can be adopted to perform FOD or power efficiency optimization in the wireless power system 100. The first step of the power calculating method is to sample the input current or the output current of the regulator, that is, the detecting current, to derive a current sampling value, meanwhile, sample the input voltage or the output voltage of the regulator, that is, the detecting voltage, to derive a voltage sampling value. It is worth noting that the related descriptions of the decision of whether the input current (voltage) or the output current (voltage) is sampled, the sampling topology adopted in the embodiment, and the voltage and current sampling techniques can be referred to the corresponding descriptions in the first embodiment of FIG. 3, and will not be interpreted further hereinafter.

Then, multiply the current sampling value to the voltage sampling value to derive a product, and divide the product by a power efficiency value to derive an instant receiving power value, wherein the related descriptions of the power efficiency value can be referred to the corresponding descriptions in the first embodiment of FIG. 3, and will not be interpreted further hereinafter.

In more detail, the power efficiency value is usually not a fixed number but a function of a current. In this embodiment shown in FIG. 3, the power efficiency value is a function of the sampled input or output current, that is, the current sampling value. The voltage sampling and current sampling are repeated for N times. Assume that the sampled values of the input or output voltage are V₁, V₂, . . . , V_{N}, the sampled values of the input or output current are I₁, I₂, . . . , I_{N}, and the power efficiency value corresponding to the sampled voltage values and current values are E₁, E₂, . . . , E_{N}, then the receiving power value P can be derived as follows:

$$P = \frac{\frac{{V}_{1} \cdot {I}_{1}}{{E}_{1}} + \frac{{V}_{2} \cdot {I}_{2}}{{E}_{2}} + … + \frac{{V}_{N} \cdot {I}_{N}}{{E}_{N}}}{N} \qquad ( 3 )$$

Finally, the receiving power value is transmitted to the power transmitting end of the wireless power system 100 for performing such as FOD or power efficiency optimization. The transmitting method of the receiving power value is mainly by wireless transmission which is well known by people in the skill, and will not be interpreted further hereinafter.

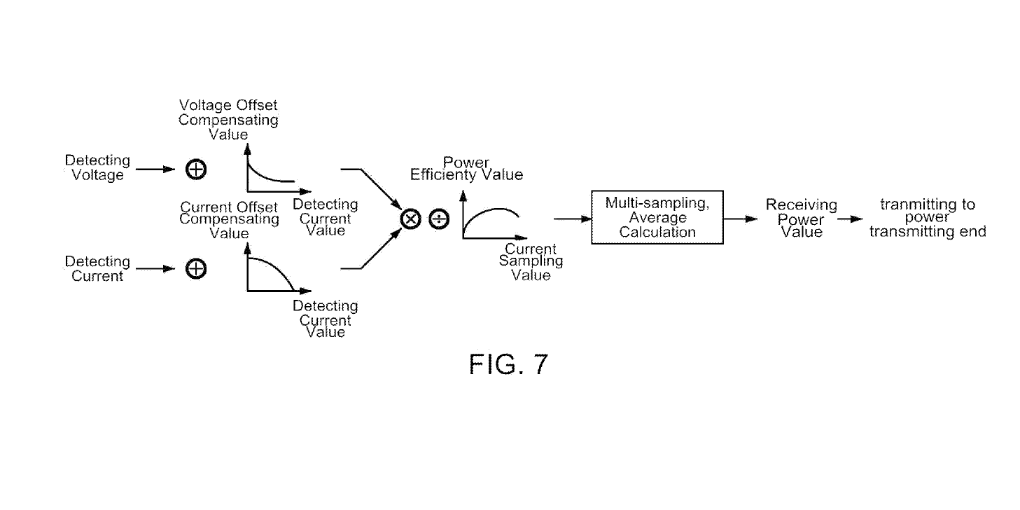

FIG. 7 is a schema showing a power calculating method of the fourth embodiment of the present invention. The difference between the fourth embodiment disclosed in FIG. 7 and the third embodiment disclosed in FIG. 6 is that the voltage offset compensation and the current offset compensation is added in the fourth embodiment. As for the rest parts of the fourth embodiment of FIG. 7, they can be directly referred to the corresponding parts of the third embodiment.

As is shown in FIG. 7, since there are possible offset in the voltage and current sampling circuits, after sampling the detecting voltage and the detecting current, a voltage offset compensating value and a current offset compensating value are added to sampled value of the detecting voltage and the detecting current respectively to derive a voltage sampling value and a current sampling value. In the real implementation, it is found that the voltage offset compensating value and the current offset compensating value can both be functions of the detecting current value for the optimized compensation effect. Nonetheless, the voltage offset compensating value and the current offset compensating value can also be fixed values, or functions of other parameters. People of the skill can optimize the decision of the voltage offset compensating value and the current offset compensating value according to the various applications.

In more detail, assume the voltage offset compensating values corresponding to the sampled values of the detecting voltage V₁, V₂, . . . , V_{N} respectively are Vₒₛ₁, Vₒₛ₂, . . . V_{osN}, the current offset compensating values corresponding to the sampled values of the detecting current I₁, I₂, . . . , I_{N} respectively are Iₒₛ₁, Iₒₛ₂, . . . , I_{osN}, and the power efficiency value corresponding to the sampled values of the detecting current I₁, I₂, . . . , I_{N} respectively are E₁, E₂, . . . , E_{N}, then the receiving power value P can be derived as follows:

$$P = \frac{\begin{matrix}\frac{( {V}_{1} + {V}_{os 1} ) \cdot ( {I}_{1} + {I}_{os 1} )}{{E}_{1}} + \frac{( {V}_{2} + {V}_{os 2} ) \cdot ( {I}_{2} + {I}_{os 2} )}{{E}_{2}} + … + \\ \frac{( {V}_{N} + {V}_{os N} ) \cdot ( {I}_{N} + {I}_{os N} )}{{E}_{N}}\end{matrix}}{N} \qquad ( 4 )$$

Finally, the receiving power value is transmitted to the power transmitting end of the wireless power system 100 for performing such as FOD or power efficiency optimization. The transmitting method of the receiving power value is mainly by wireless transmission which is well known by people in the skill, and will not be interpreted further hereinafter.

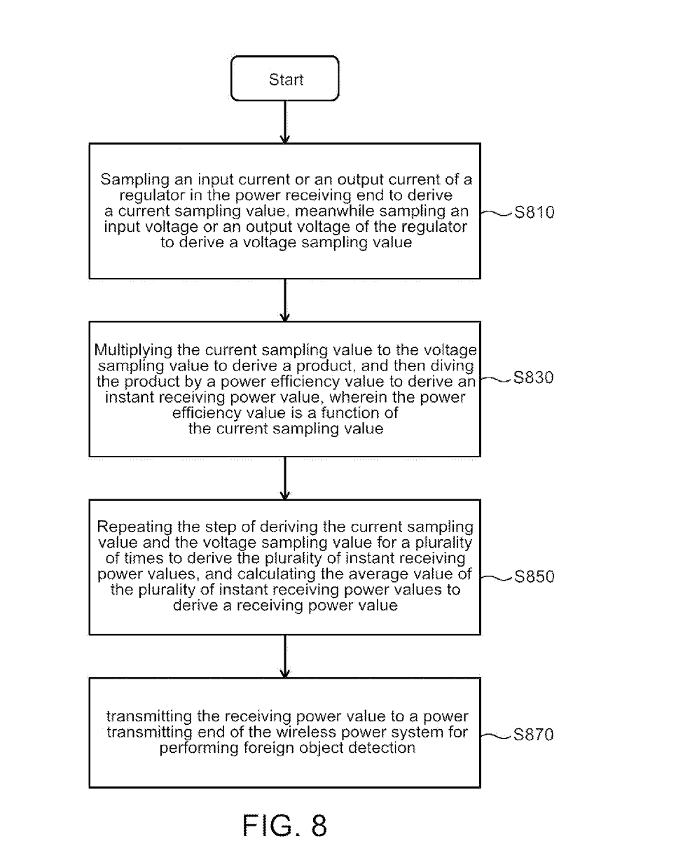

FIG. 8 is the concluded flow chart of the third embodiment of the present invention disclosed in FIG. 6. The flow chart includes the following steps:

As shown in step S810, sample an input current or an output current of a regulator in the power receiving end to derive a current sampling value, meanwhile sample an input voltage or an output voltage of the regulator to derive a voltage sampling value.

As shown in step S830, multiply the current sampling value to the voltage sampling value to derive a product, and then divide the product by a power efficiency value to derive an instant receiving power value, wherein the power efficiency value is a function of the current sampling value.

As shown in step S850, repeat the step of deriving the current sampling value and the voltage sampling value for a plurality of times to derive the plurality of instant receiving power values, and calculate the average value of the plurality of instant receiving power values to derive a receiving power value.

As shown in step S870, transmit the receiving power value to a power transmitting end of the wireless power system for performing FOD.

Besides, step S810 can further include adding a current offset compensating value to the sampled values of the input or output current to derive the current sampling value, wherein the current offset compensating value can be a function of the sampled input or output current of the regulator.

Further, step S810 can further include adding a voltage offset compensating value to the sampled values of the input or output voltage to derive the voltage sampling value, wherein the voltage offset compensating value can be a function of the sampled input or output current of the regulator.

The aforementioned description only represents the preferred embodiment of this invention, without any intention to limit the scope of this invention thereto. Various equivalent changes, alterations, or modifications based on the claims of this invention are all consequently viewed as being embraced by the scope of this invention.

What is claimed is:

1. A power calculating method, adapted to a power receiving end of a wireless power system for performing foreign object detection, comprising the following steps:
multi-sampling an input current or an output current of a regulator in the power receiving end to derive a current array, and performing a root-men-square calculation on the current array to derive a current RMS value;
multi-sampling an input voltage or an output voltage of the regulator to derive a voltage array, and performing a root-men-square calculation on the voltage array to derive a voltage RMS value;
multiplying the voltage RMS value to the current RMS value and a cosine of an angle to derive a regulating power value, wherein the angle is correlated to a signal phase difference between the multi-sampled input voltage or output voltage of the regulator and the multi-sampled input current or output current of the regulator;
dividing the regulating power value by a power efficiency value to derive a receiving power value, wherein the power efficiency value is a function of the current RMS value; and
transmitting the receiving power value to a power transmitting end of the wireless power system for performing foreign object detection.

2. The power calculating method of claim 1, wherein the step of deriving the current RMS value further comprises adding a current offset compensating value to the multi-sampled values of the input or output current to derive the current array.

3. The power calculating method of claim 2, wherein the current offset compensating value is a function of the multi-sampled input or output current of the regulator.

4. The power calculating method of claim 1, wherein the step of deriving the voltage RMS value further comprises adding a voltage offset compensating value to the multi-sampled values of the input or output voltage to derive the voltage array.

5. The power calculating method of claim 4, wherein the voltage offset compensating value is a function of the multi-sampled input or output current of the regulator.

6. A power calculating method, adapted to a power receiving end of a wireless power system for performing foreign object detection, comprising the following steps:
sampling an input current or an output current of a regulator in the power receiving end to derive a current sampling value, meanwhile sampling an input voltage or an output voltage of the regulator to derive a voltage sampling value;
multiplying the current sampling value to the voltage sampling value to derive a product, and then dividing the product by a power efficiency value to derive an instant receiving power value, wherein the power efficiency value is a function of the current sampling value;
repeating the step of deriving the current sampling value and the voltage sampling value for a plurality of times to derive the plurality of instant receiving power values, and calculating the average value of the plurality of instant receiving power values to derive a receiving power value; and
transmitting the receiving power value to a power transmitting end of the wireless power system for performing foreign object detection.

7. The power calculating method of claim 6, wherein the step of sampling the input current or the output current further comprises adding a current offset compensating value to the sampling value of the input current or the output current to derive the current sampling value.

8. The power calculating method of claim 7, wherein the current offset compensating value is a function of the sampled input or output current of the regulator.

9. The power calculating method of claim 6, wherein the step of sampling the input voltage or the output voltage further comprises adding a voltage offset compensating value to the sampling value of the input voltage or the output voltage to derive the voltage sampling value.

10. The power calculating method of claim 9, wherein the voltage offset compensating value is a function of the sampled input or output current of the regulator.
